(19) United States
(12) Patent Application Publication
(10) Pub. No.: US 2020/0066816 A1
(43) Pub. Date: Feb. 27, 2020

(54) DISPLAY SCREENS, DISPLAY DEVICES AND METHODS FOR MANUFACTURING DISPLAY SCREENS

(71) Applicant: Kunshan Go-Visionox Opto-Electronics Co., Ltd., Kunshan (CN)

(72) Inventor: Ying ZHAO, Kunshan (CN)

(21) Appl. No.: 16/669,548

(22) Filed: Oct. 31, 2019

Related U.S. Application Data
(63) Continuation of application No. PCT/CN2018/089651, filed on Jun. 1, 2018.

(30) Foreign Application Priority Data
Sep. 30, 2017 (CN) 201710938802.0
Feb. 9, 2018 (CN) 201810136942.0

(51) Int. Cl. H01L 27/32

(52) U.S. Cl. CPC H01L 27/3246; H01L 27/3258; H01L 27/3211

(57) ABSTRACT

Display screens, display devices, and methods for manufacturing a display screen, the display screen includes a light-emitting layer. The light-emitting layer includes a first region provided with an opening for transmitting light; and a second region for display.

### CROSS-REFERENCES TO RELATED APPLICATIONS

This application is a continuation application of PCT Patent Application No. PCT/CN2018/089651, entitled “DISPLAY SCREENS, DISPLAY DEVICES AND METHODS FOR MANUFACTURING DISPLAY SCREEN”, filed on Jun. 1, 2018; which claims priority to Chinese application No. 2018101369420, entitled “DISPLAY SCREEN AND DISPLAY APPARATUS”, filed on Feb. 9, 2018, and priority to Chinese application No. 2017109388020, entitled “DISPLAY SCREEN AND DISPLAY APPARATUS” filed on Sep. 30, 2017, the contents of which are incorporated by reference herein in their entirety.

### FIELD

The present disclosure relates to the technical field of display, and particularly, relates to display screens, display devices, and methods for manufacturing display screens.

### BACKGROUND

In the conventional technology, the display screen includes an effective display region and a non-display region, the effective display region has a display function, and the non-display region does not have a display function, and is generally used for setting functional devices such as a front camera. For a smart phone with a touch control function, the effective display region can be configured to display the human-machine interface and provide an application for operating the human-machine interface. For example, the effective display region can display a piece of video played by the video playback application of the smartphone.

### SUMMARY

Accordingly, it is necessary to provide display screens, display devices, and methods for manufacturing a display screen in view of the technical problem of low screen-to-body ratio of display.

A display screen includes a light-emitting layer, the light-emitting layer includes a first region provided with an opening for transmitting light; and a second region for display.

In an embodiment, the light-emitting layer includes a plurality of first regions and a plurality of second regions, at least a first-type light-emitting unit is formed by one first region and one second region adjacent to the first region.

In an embodiment, the number of the first-type light-emitting unit is plural.

In an embodiment, the first-type light-emitting unit includes any one of a red sub-pixel, a green sub-pixel, and a blue sub-pixel.

In an embodiment, in the red sub-pixel, a ratio of an area of the first region to an area of the second region is 1:3 to 3:3.

In an embodiment, in the green sub-pixel, a ratio of an area of the first region to an area of the second region is 1:2 to 2:1.

In an embodiment, in the blue sub-pixel, a ratio of an area of the first region to an area of the second region is 1:1.5 to 1.5:1.

In an embodiment, the light-emitting layer further includes a plurality of second-type light-emitting units, and the second-type light-emitting unit has the second region but does not have the first region.

In an embodiment, the plurality of first-type light-emitting units are gathered together to form a light-transmitting display region, and the plurality of second-type light-emitting units are gathered together to form a display region.

A display device, includes: a display screen according to any one of the foregoing display screens; and an under-screen photosensitive module capable of sensing light irradiated through the display screen.

In an embodiment, the under-screen photosensitive module includes at least one of a photoelectric sensor and a front camera.

In an embodiment, the under-screen photosensitive module is embedded under the display screen by 4 mm to 6 mm.

A method for manufacturing the display screen according to any one of the foregoing display screens, includes: forming an opening for transmitting light in a pixel defining layer when forming the pixel defining layer; and enabling a portion where the opening being located uncovered by light-emitting layer material forming a light-emitting layer when forming the light-emitting layer.

The technical solutions provided herein has the following beneficial technical effect:

The light-emitting layer includes a first region provided with an opening for transmitting light and a second region for display. The first regions and the second regions are arranged in combination, the external light can be transmitted into inside the display screen and provide necessary light intensity under the display screen, and a photosensitive module can be arranged under the display screen where there is a certain ratio of first region to the screen. The non-display region is thus omitted to increase the screen-to-body ratio.

### BRIEF DESCRIPTION OF THE DRAWINGS

FIG. 1 is a schematic diagram of a layered structure of a display screen according to an embodiment of the present disclosure.

FIG. 2 is a partial cross-sectional view of a display screen according to an embodiment of the present disclosure.

FIG. 3 is another partial cross-sectional view of a display screen according to an embodiment of the present disclosure.

### DETAILED DESCRIPTION OF THE INVENTION

As mentioned above, a display screen usually includes a display region and a non-display region. The presence of the non-display region may reduce the screen-to-body ratio of the display screen, resulting in unfavorable user experience.

A method for manufacturing a display screen may include the following steps.

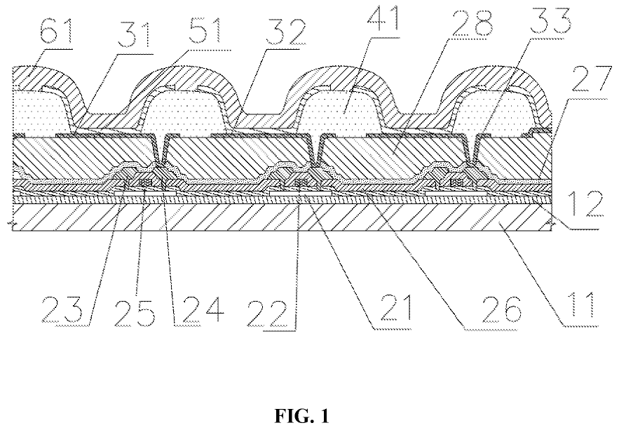

Referring to FIG. 1, first, a substrate 11 is provided. The substrate 11 has a first sub-pixel region, a second sub-pixel region, and a third sub-pixel region. A set of the first sub-pixel region, the second sub-pixel region, and the third sub-pixel region may form one pixel region. The substrate 11 may have a plurality of pixel regions. In an embodiment, the first sub-pixel region may be a sub-pixel region emitting red light. The second sub-pixel region may be a sub-pixel region emitting green light. And the third sub-pixel region may be a sub-pixel region emitting blue light.

The substrate 11 may be formed of a suitable material such as a glass material, a metal material, or a plastic material including polyethylene terephthalate (PET), polyethylene naphthalate (PEN), or polyimide etc. A thin film transistor (TFT) may be arranged on the substrate 11. In an embodiment, before forming the TFT, an additional layer such as a buffer layer 12 may be formed on the substrate 11. The buffer layer 12 may be formed on the entire surface of the substrate 11 or may be formed by patterning.

The buffer layer 12 may be a layered structure formed of a material such as PET, PEN, polyacrylate, and/or polyimide in the form of a single layer or multi-layered stack. The buffer layer 12 may also be formed of silicon oxide or silicon nitride, or may include a composite layer of an organic material and/or an inorganic material.

The TFT may control the emission of each sub-pixel, or may control the amount that each sub-pixel emits when emitting light. The TFT may include a semiconductor layer 21, a gate electrode 22, a source electrode 23, and a drain electrode 24.

The semiconductor layer 21 may be formed of an amorphous silicon layer, a silicon oxide layer, a metal oxide, or a polysilicon layer, or may be formed of an organic semiconductor material. In an embodiment, the semiconductor layer 21 includes a channel region and source and drain regions doped with dopants.

The semiconductor layer 21 may be covered with a gate insulating layer 25. The gate electrode 22 may be located on the gate insulating layer 25. In general, the gate insulating layer 25 may cover the entire surface of the substrate 11. In an embodiment, the gate insulating layer 25 may be formed by patterning. The gate insulating layer 25 may be formed of silicon oxide, silicon nitride, or other insulating organic or inorganic material in consideration of adhesion with an adjacent layer, formability of a stack target layer, and surface flatness. The gate electrode 22 may be covered by an interlayer insulating layer 26 formed of silicon oxide, silicon nitride, and/or other suitable insulating organic or inorganic material. A portion of the gate insulating layer 25 and the interlayer insulating layer 26 may be removed, and a contact hole is formed after the removal to expose a predetermined region of the semiconductor layer 21. The source electrode 23 and the drain electrode 24 may contact the semiconductor layer 21 via the contact hole. The source electrode 23 and the drain electrode 24 may be formed of a single material layer or composite material layer of aluminum (Al), platinum (Pt), palladium (Pd), silver (Ag), magnesium (Mg), gold (Au), nickel (Ni), neodymium (Nd), iridium (Ir), Chromium (Cr), lithium (Li), calcium (Ca), molybdenum (Mo), titanium (Ti), tungsten (W) and copper (Cu) or other suitable metals.

A protective layer 27 formed of silicon oxide, silicon nitride, and/or other suitable insulating organic or inorganic material may cover the TFT. The protective layer 27 covers all or a portion of the substrate 11. Since a TFT having a complex layer structure is located under the protective layer 27, the top surface of the protective layer 27 may not be sufficiently flat. Therefore, it is necessary to form a planarization layer 28 on the protective layer 27 so as to form a sufficiently flat top surface.

After the planarization layer 28 is formed, a via hole may be formed in the protective layer 27 and the planarization layer 28 to expose the source electrode 23 and the drain electrode 24 of the TFT.

Then a first sub-pixel electrode 31, a second sub-pixel electrode 32, and a third sub-pixel electrode 33 are formed on the planarization layer 28. The first sub-pixel electrode 31 is formed in the first sub-pixel region, the second sub-pixel electrode 32 is formed in the second sub-pixel region, and the third sub-pixel electrode 33 is formed in the third sub-pixel region. The first sub-pixel electrode 31, the second sub-pixel electrode 32, and the third sub-pixel electrode 33 may be simultaneously or synchronously formed. Each of the first sub-pixel electrode 31, the second sub-pixel electrode 32, and the third sub-pixel electrode 33 may be electrically connected to the TFT through a via hole. The first sub-pixel electrode 31, the second sub-pixel electrode 32, and the third sub-pixel electrode 33 are generally referred to as anodes.

Each of the first sub-pixel electrode 31, the second sub-pixel electrode 32, and the third sub-pixel electrode 33 may be formed as a transparent electrode (transflective electrode) or a reflective electrode. When the first sub-pixel electrode 31, the second sub-pixel electrode 32, and the third sub-pixel electrode 33 are formed as transparent electrodes, the first sub-pixel electrode 31, the second sub-pixel electrode 32, and the third sub-pixel electrode 33 can be form of indium tin oxide (ITO), indium zinc oxide (IZO), zinc oxide (ZnO), indium oxide (In₂O₃), indium gallium oxide (IGO), or aluminum zinc oxide (AZO). When the first sub-pixel electrode 31, the second sub-pixel electrode 32, and the third sub-pixel electrode 33 are formed as reflective electrodes, a reflective electrode layer may be formed by superposing a reflective layer and an auxiliary layer. The reflective layer may be composed of any one or a combination of silver (Ag), magnesium (Mg), aluminum (Al), platinum (Pt), palladium (Pd), gold (Au), nickel (Ni), neodymium (Nd), iridium (Ir), and chromium (Cr). The auxiliary layer is formed of a transparent electrode material such as indium tin oxide (ITO), indium zinc oxide (IZO), zinc oxide (ZnO), and indium oxide (In₂O₃). The structures and materials of the first sub-pixel electrode 31, the second sub-pixel electrode 32, and the third sub-pixel electrode 33 are not limited thereto, and are variable.

As shown in FIG. 1, after the first sub-pixel electrode 31, the second sub-pixel electrode 32, the third sub-pixel electrode 33, and a pixel defining layer (PDL) 41 may be formed. The formed PDL 41 covers the first sub-pixel electrode 31, the second sub-pixel electrode 32, and the third sub-pixel electrode 33 at the same time. The PDL may define a sub-pixel by having an opening corresponding to each sub-pixel, i.e., an opening exposing a central portion of each sub-pixel. The PDL may be formed of a single material layer or a composite material layer of an organic material such as polyacrylate and polyimide or an inorganic material. The PDL may be formed in the following manner: a layer of PDL is formed on an entire surface of the substrate 11 using a material suitable for PDL, so as to cover the first sub-pixel electrode 31, the second sub-pixel electrode 32, and the third sub-pixel electrode 33. Then, the PDL layer is patterned to expose the central portions of the first sub-pixel electrode 31, the second sub-pixel electrode 32, and the third sub-pixel electrode 33.

The light-emitting layer 51 may be formed by vapor-deposition of a light-emitting material. The evaporated light-emitting material covers a portion of the first sub-pixel electrode 31 not covered with the PDL layer, covers a portion of the second sub-pixel electrode 32 not covered with the PDL layer, covers a portion of the third sub-pixel electrode 33 not covered by the PDL layer, and covers the top surface of the PDL layer. A precise metal mask can be utilized to evaporate light-emitting materials that emit red, green, and blue lights.

Then a counter electrode 61 is formed by vapor-deposition, and the counter electrode 61 covers the first sub-pixel region, the second sub-pixel region, and the third sub-pixel region. The counter electrode 61 may be integrally formed with respect to a plurality of sub-pixels so as to cover the entire display region. The counter electrode 61 is commonly referred to as a cathode.

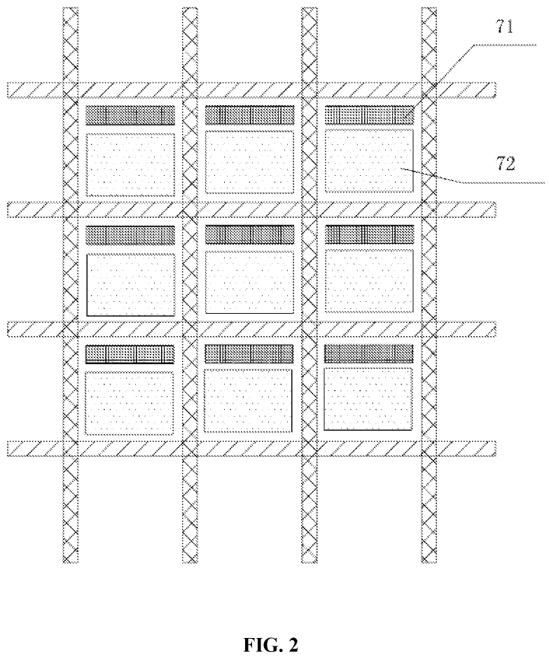

The counter electrode 61 contacts the electrode power supply line outside the display region, so that the electrode power supply line can receive an electric signal. The counter electrode 61 may be formed as a transparent electrode or a reflective electrode. When the counter electrode 61 is formed as a transparent electrode, the counter electrode 61 may include a layer formed by depositing one or a plurality of mixed materials of Li, Ca, LiF/Ca, LiF/Al, Al, and Mg in a direction toward the light-emitting layer, and include an auxiliary electrode or a bus electrode line formed of a transparent (transflective) material of ITO, IZO, ZnO, or In₂O₃. When the counter electrode 61 is formed as a reflective electrode, the counter electrode 61 may have a layer including one or more materials of Li, Ca, LiF/Ca, LiF/Al, Al, Ag, and Mg. The configuration and material of the counter electrode 61 are not limited thereto. FIG. 2 shows a partial cross-sectional view of the display screen. A sub-pixel 72 defined by a TFT trace 71 and a PDL layer is shown in the FIG. 2.

In a provided embodiment, the display screen includes a light-emitting layer, which includes a first region provided with an opening 73 for transmitting light and a second region for display.

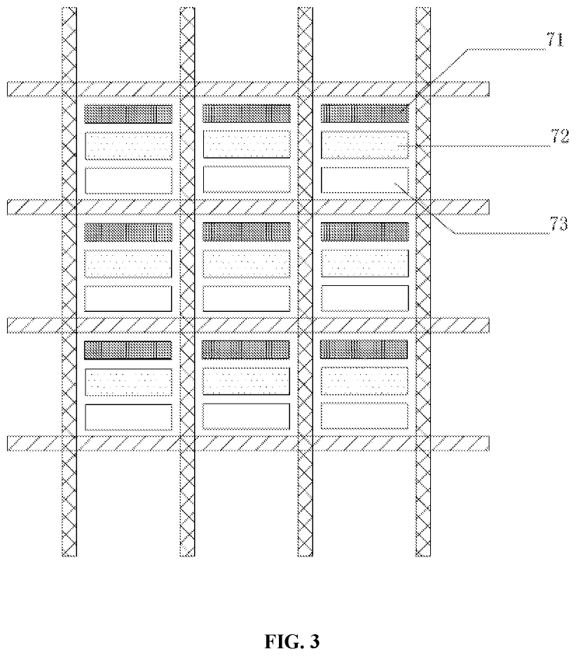

FIG. 3 shows a partial cross-sectional view of a display screen, in which a TFT trace 71, a sub-pixel 72 defined by a PDL layer, and an opening 73 are disclosed. The sub-pixel 72 defined by the PDL layer is a central portion of the first sub-pixel electrode 31, the second sub-pixel electrode 32, and the third sub-pixel electrode 33 exposed in the PDL layer patterning process, and is formed after the vapor-deposition of the light-emitting layer. The opening 73 defined by the PDL layer is a sub-pixel electrode-free opening region formed by exposing a spacing portion between the first sub-pixel electrode 31, the second sub-pixel electrode 32, and the third sub-pixel electrode 33 in the PDL layer patterning process. That is, in the PDL layer patterning process, in addition to exposing the central portions of the first sub-pixel electrode 31, the second sub-pixel electrode 32, and the third sub-pixel electrode 33, the first sub-pixel electrode 31, a spacing region among the first sub-pixel electrode 31, the second sub-pixel electrode 32, and the third sub-pixel electrode 33 is also exposed, i.e., regions on the planarization layer 28 where the sub-pixel electrode is not formed are exposed. The sub-pixel 72 and the opening 73 may be simultaneously formed in the PDL layer patterning process, but the subsequent manufacturing of the light-emitting layer and the counter electrode 61 is not performed on the opening 73. Therefore, the opening 73 in the present disclosure is a hole structure on the planarization layer 28 without any electrode and film structures, and the external light can enter the display screen completely through the opening 73 without being blocked.

In FIG. 2, when the light-emitting layer is regarded as a layered structure, the light-emitting layer includes a second region for display. In FIG. 3, when the light-emitting layer is regarded as a layered structure, the light-emitting layer includes a first region provided with an opening 73 for transmitting light and includes a second region for display. The first region is used to provide the opening 73 and the second region is used to provide the sub-pixel 72.

As can be seen from the foregoing description, the formation of the first region can be implemented by providing the opening 73 on the PDL layer, and the formation of the second region can be implemented by providing the opening 73 on the PDL layer and performing vapor-deposition in a subsequent process. Detailed explanation has been made in the manufacturing process of the foregoing display screen and is omitted for brevity.

The size of the first region and the size of the sub-pixels 72 are at the same level, typically in microns, which requires using a magnifying glass to be well observed. In the present disclosure, the light-emitting layer includes a first region provided with an opening 73 for transmitting light and includes a second region for display, the first regions and the second regions are arranged in combination throughout the display screen, that is, when viewed with the naked eyes, the entire display screen can display pictures, i.e., a so-called full screen. In the conventional display screen, in order to ensure that the front camera or other photosensitive function module can obtain a certain intensity of light, a non-display region is usually provided on the display screen, and the front camera or the photosensitive function module is arranged in the non-display region. While in the present disclosure, the front camera or other photosensitive function module can be hidden under a display screen having a certain proportion of the first region due to the display screen having the transmitting light first region, thus no position for the front camera or the photosensitive function module have to be reserved, therefore, the non-display region above the effective display region may be omitted, the screen-to-body ratio may be increased, and the user experience may be optimized, so that the technical problem of unfavorable user experience due to the presence of the non-display region may be addressed.

In addition, the display screen may further include a substrate, a buffer layer, a TFT, a gate insulating layer, an interlayer insulating layer, a protective layer, a planarization layer, a pixel defining layer, and a counter electrode. The TFT includes a semiconductor layer, a gate electrode, source and drain electrodes, and a first sub-pixel electrode, a second sub-pixel electrode, and a third sub-pixel electrode are formed on the planarization layer. In particular, the structural relationship between the substrate, the buffer layer, the TFT, the gate insulating layer, the interlayer insulating layer, the protective layer, the planarization layer, the pixel defining layer, the light-emitting layer, the counter electrode, the first sub-pixel electrode, the second sub-pixel electrode, and the third sub-pixel electrode has been explained in detail in the manufacturing process of the display screen and is omitted for brevity.

In an embodiment, the light-emitting layer includes a plurality of first regions and a plurality of second regions, one first region of the plurality of first regions and one second region of the plurality of second regions adjacent and corresponding to the first region form one first-type light-emitting unit.

In an embodiment, the light-emitting layer further includes a plurality of second-type light-emitting units, which do not have the first region. For example, in FIG. 2, the second-type light-emitting unit includes a second region for display but does not have the first region.

An active matrix organic light-emitting diode (AMOLED) is a display technology to deposit or integrate organic light-emitting diode (OLED) pixels onto a TFT array to control the magnitude of current flowing into each OLED pixel by the TFT array, thereby determining the brightness intensity of each pixel. In the embodiments provided herein, the same driving algorithm may be used for the first-type light-emitting unit and the second-type light-emitting unit to control the light emission, or different driving algorithms may be used for the first-type light-emitting unit and the second-type light-emitting unit.

In a specific application, for example, for a display screen, no change is made to the display portion of the display screen, i.e. a plurality of second-type light-emitting units are arranged. A plurality of first-type light-emitting units are arranged at positions in the display screen for the front camera or the photosensitive function module. This has the advantage that the front camera or the photosensitive function module needs a certain light intensity or a certain amount of light-sensing to achieve a good functional effect, and the front camera or the photosensitive functional module is located at the lower layer of the first-type light-emitting unit, since the opening 73 of the first region in the first-type light-emitting unit can transmit light, the light intensity can be effectively increased, so that the light intensity required by the front camera or the photosensitive function module can be satisfied.

Furthermore, in a provided embodiment, the number of the first-type light-emitting unit is plural. It should be understood that increasing the number of first-type light-emitting unit may increase the intensity of light entering the display screen. The edge of the display screen is usually configured for setting the front or light sensitive function module, so the number of first-type light-emitting unit is favorably arranged over the edge of the display screen.

In an embodiment, the first-type light-emitting unit includes any one of a red sub-pixel, a green sub-pixel, and a blue sub-pixel.

According to the method for manufacturing the display screen and the AMOLED technology, each first-type light-emitting unit is independently controlled to emit light, and therefore, the first-type light-emitting unit may include any one of a red sub-pixel, a green sub-pixel, and a blue sub-pixel. The first-type light-emitting units composed of the red sub-pixels, the green sub-pixels, and the blue sub-pixels are evenly distributed, so as to effect the white balance.

In an embodiment, in the red sub-pixel, the ratio of the area of the first region to the area of the second region is 1:3 to 3:1; further, in the green sub-pixel, the ratio of the area of the first region to the area of the second region is 1:2 to 2:1; further, in the blue sub-pixel, the ratio of the area of the first region to the area of the second region is 1:1.5 to 1.5:1. In the range of the above ratios, the display screen can transmit a certain intensity of light to meet the requirement of the front camera or the photosensitive function module under the screen. The display effect seen by the naked eye will not be affected. The area ratios of the sub-pixels of different colors are different, this is mainly in consideration that the brightness efficiencies of the light-emitting substances of the different colors are different, so as to reduce the influence by the opening on the light emitting efficiencies of sub-pixels of different colors, thereby ensuring that the difference in color display is not perceived by the naked eyes when the first-type light-emitting unit and the second-type light-emitting unit are simultaneously displaying.

In the embodiment provided herein, the ratios of the areas of the first regions to the areas of the second regions of the red sub-pixel, the green sub-pixel, and the blue sub-pixel of the light-emitting unit of the first-type may be set to be the same to facilitate mass production and manufacture. In an alternative embodiment provided herein, the ratio of the area of the first region to the area of the second region may also be set according to actual needs.

In a provided embodiment, in a display screen, a plurality of first-type light-emitting units are gathered together to form a light-transmitting display region, and a plurality of second-type light-emitting units are gathered together to form a display region.

Specifically, the first-type light-emitting unit and the second-type light-emitting unit may be provided according to light intensity requirements of different regions or portions of the display screen. In a specific application, a plurality of first-type light-emitting units are arranged at positions in the display screen for the front camera or the photosensitive function module, and are gathered together to form a light-transmitting display region. In this way, the lighting requirements of the front camera or the light-sensitive function module can be satisfied, and in the regions or portions for display of the display screen, a plurality of second-type light-emitting units are gathered together to form a display region.

In a provided embodiment, a display device is also provided. The display device includes: a display screen including a light-emitting layer including a first region provided with an opening 73 for transmitting light and including a second region for display; and an under-screen photosensitive module capable of sensing the light irradiated through the display screen.

The display screen, the first region, and the second region have been described in details in the foregoing sections and are omitted for brevity.

The display device herein can be understood as a stand-alone product such as a mobile phone, a tablet computer, and the like. The display device may also include a DC power supply, a DC or an AC power interface, a memory, a processor, and the like. The DC power supply may be a lithium battery in a specific application. The DC power supply or AC power interface may be a micro-USB plug-in interface in a specific application. The memory may be a flash memory chip. The processor may be a CPU having an arithmetic function, a single-chip computer, or the like.

In a provided embodiment, the under-screen photosensitive module includes at least one of a photoelectric sensor and a front camera. The photoelectric sensor may be, in particular, an infrared sensor for detecting whether a human face is close to the display screen. The under-screen photosensitive module may be provided as needed. For example, the under-screen photosensitive module may be a photoelectric sensor, a front camera, or both a photoelectric sensor and a camera.

In a provided embodiment, the under-screen photosensitive module is embedded under the display screen by 4 mm to 6 mm. In the display screen, as the depth of light propagation gradually increases, the light intensity is attenuated. When the under-screen photosensitive module is embedded in a depth of 4 mm to 6 mm under the display screen, not only a stable assembly of the under-screen photosensitive module can be ensured, but also a light intensity within the required range can be guaranteed.

Although the disclosure is illustrated and described herein with reference to specific embodiments, the disclosure is not intended to be limited to the details shown. Rather, various modifications may be made in the details within the scope and range of equivalents of the claims and without departing from the invention.

1. A display screen comprising a light-emitting layer, the light-emitting layer comprising:
a first region provided with an opening for transmitting light ; and
a second region for display.

2. The display screen according to claim 1, wherein the light-emitting layer comprises a plurality of first regions and a plurality of second regions, at least a first-type light-emitting unit being formed by one first region and one second region adjacent to the first region.

3. The display screen according to claim 2, wherein the number of the first-type light-emitting units is plural.

4. The display screen according to claim 3, wherein the first-type light-emitting unit comprises any one of a red sub-pixel, a green sub-pixel, and a blue sub-pixel.

5. The display screen according to claim 4, wherein in the red sub-pixel, a ratio of an area of the first region to an area of the second region is 1:3 to 3:1.

6. The display screen according to claim 4, wherein in the green sub-pixel, a ratio of an area of the first region to an area of the second region is 1:2 to 2:1.

7. The display screen according to claim 4, wherein in the blue sub-pixel, a ratio of an area of the first region to an area of the second region is 1:1.5 to 1.5:1.

8. The display screen according to claim 1, wherein the light-emitting layer further comprises a plurality of second-type light-emitting units, and the second-type light-emitting unit has the second region but does not have the first region.

9. The display screen according to claim 8, wherein the plurality of first-type light-emitting units are gathered together to form a light-transmitting display region, and the plurality of second-type light-emitting units are gathered together to form a display region.

10. A display device, comprising:
a display screen comprising a light-emitting layer, the light-emitting layer comprising:
a first region provided with an opening for transmitting light; and
a second region for display; and
an under-screen photosensitive module sensing light irradiated through the display screen.

11. The display device according to claim 10, wherein the under-screen photosensitive module comprises at least one of a photoelectric sensor and a front camera.

12. The display device according to claim 10, wherein the under-screen photosensitive module is embedded under the display screen by 4 mm to 6 mm.

13. A method for manufacturing a display screen, comprising:
forming an opening for transmitting light in a pixel defining layer when forming the pixel defining layer; and
enabling a portion of the pixel defining layer where the opening being located uncovered by light-emitting layer material to form a light-emitting layer when forming the light-emitting layer.
